(19) United States
(12) Patent Application Publication
(10) Pub. No.: US 2015/0187964 A1
(43) Pub. Date: Jul. 2, 2015

(54) METHOD OF NON-BEZEL ARRAY OF SOLAR CELLS

(71) Applicant: Hyundai Motor Company, Seoul (KR)

(72) Inventor: Kyoung Jin Jeong, Seoul (KR)

(21) Appl. No.: 14/569,728

(22) Filed: Dec. 14, 2014

(30) Foreign Application Priority Data
Dec. 30, 2013 (KR) 10-2013-0167775

(51) Int. Cl. H01L 31/0203; H01L 31/18; H01L 31/042

(52) U.S. Cl. CPC H01L 31/0203; H01L 31/042; H01L 31/188

(57) ABSTRACT

The present invention provides a solar cell array having no bezel between solar cell modules and a method for fabricating the solar cell array. The method for fabricating the solar cell array provides advantages, particularly when a solar cell panel is installed on the top of a panoramic roof in a vehicle, by minimizing the connection gaps between the solar cell modules, having transparent connection wires between solar cell modules, and maximizing openness and improved sight of the panoramic roof.

### CROSS-REFERENCE TO RELATED APPLICATION

This application claims under 35 U.S.C. §119(a) the benefit of Korean Patent Application No. 10-2013-0167775 filed on Dec. 30, 2013, the entire contents of which are incorporated herein by reference.

### TECHNICAL FIELD

The present invention relates to a solar cell array structure having no bezel between solar cell arrays, which ensures sufficient openness when installed in a vehicle, and a method for fabricating the solar cell array.

### TECHNICAL FIELD

About 80 to 90% of solar cells used in a photovoltaic power generation system are crystalline solar cells using a silicon (Si) wafer. The crystalline solar cell is limited in use for a panoramic roof of a vehicle because the silicon wafer is opaque.

For this reason, a dye-sensitized solar cell which can ensure transparency is used for a panoramic roof. Because it is technically difficult to manufacture a solar cell with large area corresponding to the size of the panoramic roof, a plurality of solar cells with size of 10×10 cm, 10×20 cm or 30×30 cm arranged as an array are used.

When the solar cells are arranged using the conventional method, the openness of the panoramic roof is not ensured because of the overlapping of the cells or the presence of wires for connecting the cells.

To overcome this problem, Toyota (Japan) installs the solar cell on the car body rather than on a sunroof. However, it is not a fundamental solution because it is disadvantageous in terms of manufacturing process cost and.

Accordingly, in order to ensure transmittance and openness when installing a solar cell in a vehicle, the present invention provides a method for arranging solar cells such that connection wires between the solar cells are not seen.

The above information disclosed in this Background Art section is only for enhancement of understanding of the background of the invention and therefore it may contain information that does not form the prior art that is already known in this country to a person of ordinary skill in the art.

### SUMMARY OF THE INVENTION

The present invention provides solutions to the above-described problems associated with the related art.

In one aspect, the present invention provides a method for fabricating a solar cell array, which comprises: providing a solar cell module which includes a transparent electrode on the substrate; and bonding a plurality of the solar cell modules by connecting connection parts of an upper solar cell module and a lower solar cell module. In particular, the upper solar cell module and the lower solar cell module may be dislocated by about 100 μm to 10 mm to each other. The method may further include, after providing the solar cell module, forming a pattern having a width of about 1 to 50 μm on a first side of the substrate using one selected from the group consisting of Ag, Ag alloy, Cu, Cu alloy, Sn, Sn alloy, Ag—Cu core shell, Cu—Sn core shell, titanium (Ti), vanadium (V), chromium (Cr), manganese (Mn), cobalt (Co), nickel (Ni), copper (Cu), silver (Ag), gold (Au), iron (Fe) and combinations thereof, or the same metal as a transparent electrode formed on a first side of the substrate. In certain embodiments, the substrate may be a glass substrate or a polymer substrate.

In an exemplary embodiment, the transparent electrode may be, but not limited to, a transparent conductive material which includes zinc oxide (ZnO), ZnO:B, ZnO:Al, ZnO:H, tin oxide (SnO₂), SnO₂:F, indium tin oxide (ITO) or fluorine-doped tin oxide (FTO).

In an exemplary embodiment, the pattern formed on the first side of the substrate may be formed on the transparent electrode.

In an exemplary embodiment, the pattern formed on the first side of the substrate may be bonded to the transparent electrode.

In an exemplary embodiment, the pattern formed on the first side of the substrate may have a shape of diamond or honeycomb, without limitation.

In an exemplary embodiment, the pattern formed on the first side of the substrate or the transparent electrode may have four sides having the same length, and one or more patterns may be formed in a shape in which two diagonal lines bisect each other perpendicularly.

In an exemplary embodiment, wires connecting between the solar cell modules may be transparent by using a transparent electrode as a connecting wire.

In an exemplary embodiment, wires connecting between the solar cell modules may be transparent by using the pattern as a thin metal wire having a width of about 1 to 50 μm.

In another aspect, the present invention provides a method for manufacturing a panoramic roof for a vehicle. The method may include fabricating a solar cell array according to an exemplary embodiment of the present invention.

Further provided are solar cell arrays that may be fabricated by the method as described herein. Still further provided are vehicles comprising the panoramic roofs that may be manufactured with the solar cell arrays as described herein.

Other aspects and preferred embodiments of the invention are discussed infra.

### BRIEF DESCRIPTION OF THE DRAWINGS

The above and other features of the present invention will now be described in detail with reference to exemplary embodiments thereof illustrated in the accompanying drawings which are given hereinbelow by way of illustration only, and thus are not limitative of the present invention, and wherein:

FIG. 1 is a photographic view showing an exemplary conventional array of crystalline solar cell;

FIG. 2 shows photographic view of an exemplary connection wire of an array of crystalline solar cells;

FIG. 3 shows photographic view of an exemplary array of dye-sensitized solar cells which may not decrease transmittance;

FIG. 4 is a photographic view of an exemplary dye-sensitized solar cell array;

FIG. 5 is a photographic view of an exemplary dye-sensitized solar cell array installed on the top of a panoramic roof for vehicles;

FIG. 6 shows photographic views of examples of a dye-sensitized solar cell array in the related art, particularly indicating connections wires in red circles;

FIG. 7 schematically shows an exemplary solar cell module structure for minimizing a gap between solar cell modules according to an exemplary embodiment of the present invention;

FIG. 8 schematically shows a side view of an exemplary array of solar cell modules according to an exemplary embodiment of the present invention;

FIG. 9 schematically shows exemplary connection wires formed in a mesh type for the array between the solar cell modules according to an exemplary embodiment of the present invention;

FIG. 10 is a photographic view of an exemplary array of solar cell modules for maximizing the efficiency of connecting solar cell modules according to an exemplary embodiment of the present invention; and

FIG. 11 is a photographic view of exemplary connecting wires for connecting solar cell modules according to an exemplary embodiment of the present invention.

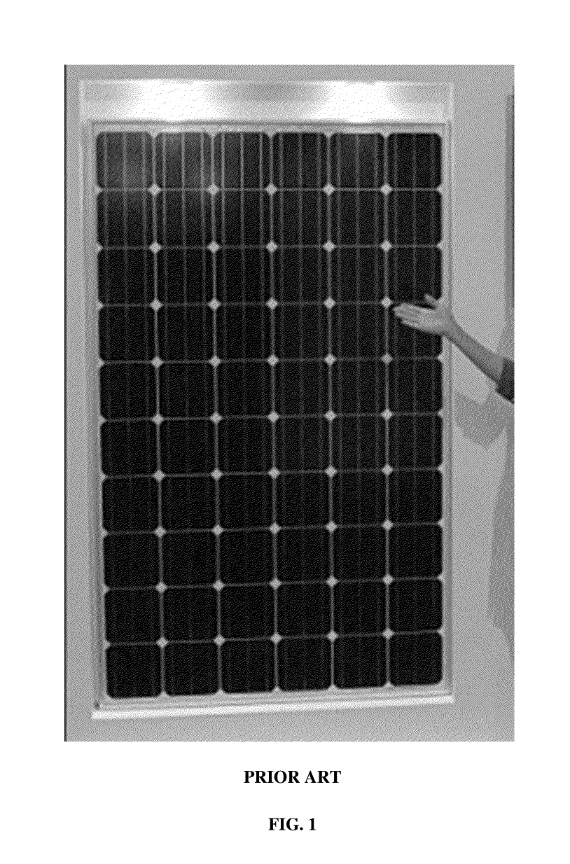

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Hereinafter reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments but also various alternatives, modifications, equivalents and other embodiments, which may be included within the spirit and scope of the invention as defined by the appended claims.

The present invention provides a solar cell array and a method of fabricating the solar cell array by ensuring transmittance of a connection part between the solar cell arrays.

Hereinafter, the present invention will be described in detail.

The present invention provides a method for fabricating a solar cell array. In an exemplary embodiment, the method may include: providing a solar cell module which includes a transparent electrode on the substrate; and bonding a plurality of the solar cell modules by connecting connection parts of an upper solar cell module and a lower solar cell module. Particularly, the upper solar cell module and the lower solar cell module may be dislocated by about 100 μm to 10 mm to each other. The method may further include, after providing the solar cell module, forming a pattern having a width of 1-50 μm on the first side of the substrate using one selected from the group consisting of silver (Ag), Ag alloy, copper (Cu), Cu alloy, tin (Sn), Sn alloy, Ag—Cu core shell, Cu—Sn core shell, titanium (Ti), vanadium (V), chromium (Cr), manganese (Mn), cobalt (Co), nickel (Ni), copper (Cu), silver (Ag), gold (Au), iron (Fe) and combinations thereof, or the same metal used for the transparent electrode formed on the first side of the substrate, prior to bonding the solar cell modules.

The substrate may be a glass substrate or a polymer substrate, and in particular, the polymer substrate may be, but not limited to, polyimide (PI) or bismaleimide-triazine (BT).

The upper solar cell module and lower solar cell module may be suitably dislocated by about 100 μm to 10 mm as noted, or suitably dislocated by about 200 μm, 300 μm, 400 μm, 500 μm, 1 mm, 2 mm, 3 mm, 4 mm, 5 mm, 6 mm, 7 mm, 8 mm, 9 mm or 9.5 mm.

The metal pattern may be formed on a substrate by inkjet printing, screen printing or dispenser printing, without limitation. In certain embodiments, the pattern having a width of about 1 to 50 μm which is formed on one side of the substrate may be formed on a transparent electrode such as fluorine-doped tin oxide (FTO), indium tin oxide (ITO) or zinc oxide (ZnO). Alternatively, the pattern or may be bonded to a transparent electrode which is formed on the first side of the substrate and may be FTO, ITO, or ZnO. In addition, The transparent electrode may be a transparent conductive material and the transparent conductive material may be, but not limited to, ZnO, ZnO:B, ZnO:Al, ZnO:H, SnO₂, SnO₂:F, ITO or FTO. Further, the transparent electrode may include electrode materials which may be used in the related field.

In certain embodiments, in the pattern having a width of about 1 to 50 μm which is formed on the first side of the substrate or the transparent electrode, the length of four sides may be the same, and one or more patterns may be formed in a shape in which two diagonal lines bisect each other perpendicularly.

In an exemplary embodiment, wires connecting between arrayed modules may be transparent by using the transparent electrode as a connection wire, or by using the patterns having a width of about 1 to 50 μm as a thin metal wire. In certain embodiments, the thin metal wire may be manufactured using silver or copper.

In another aspect, provided a panoramic roof for vehicles which may be manufactured by the method of fabricating a solar cell array as described above.

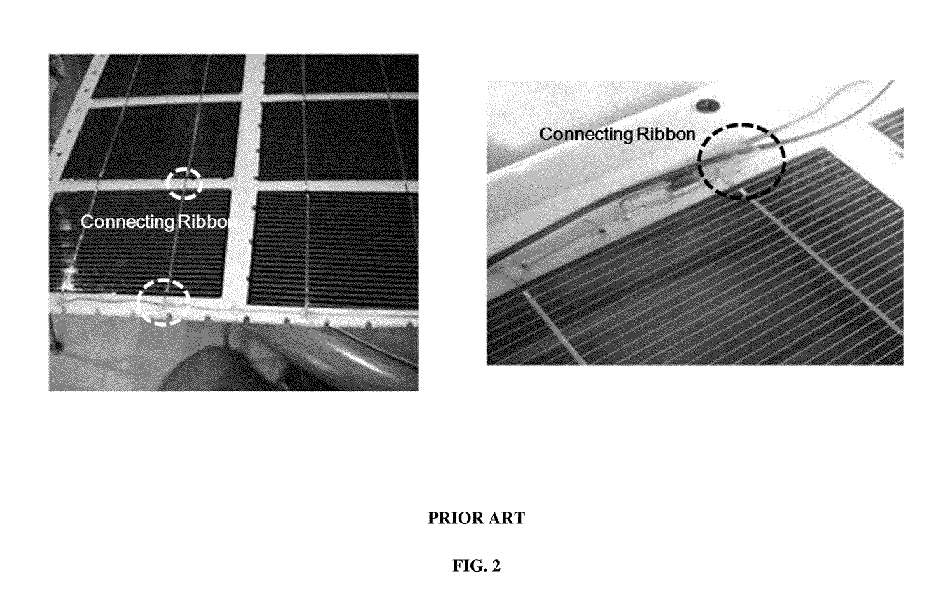

FIG. 2 shows photographic views showing connection wires of conventional crystalline solar cells in circled areas. For example, the modules may be connected using a ribbon-shaped strip made of silver or copper, thereby forming a one panel.

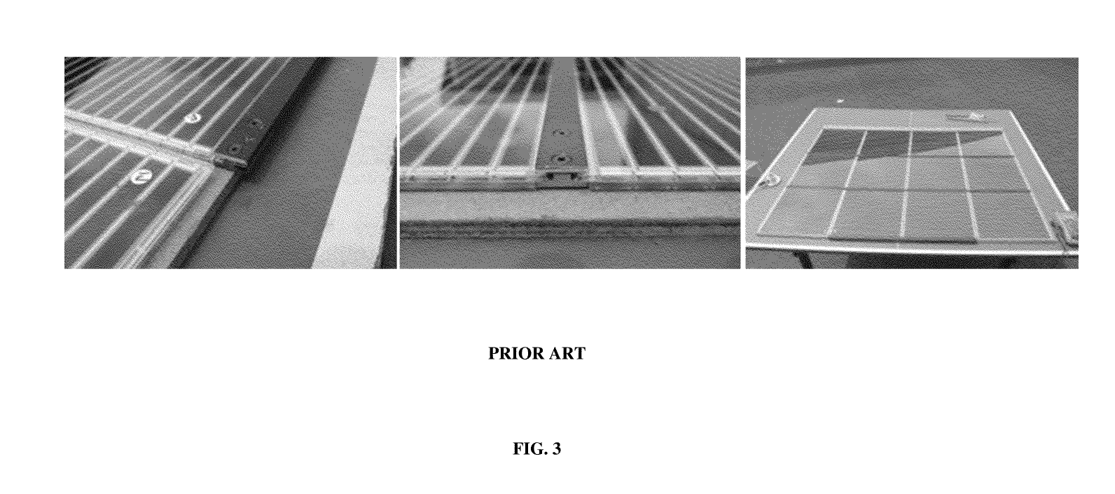

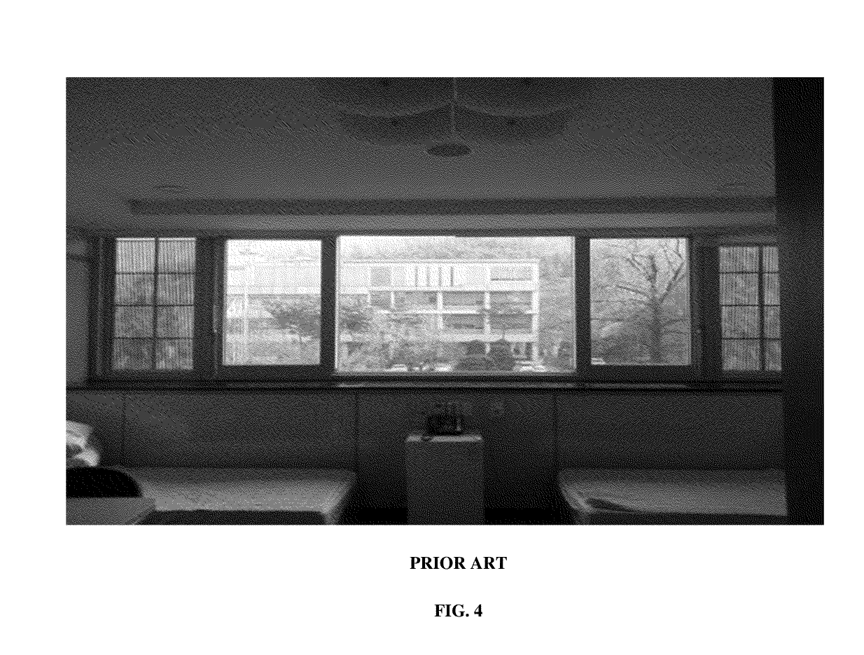

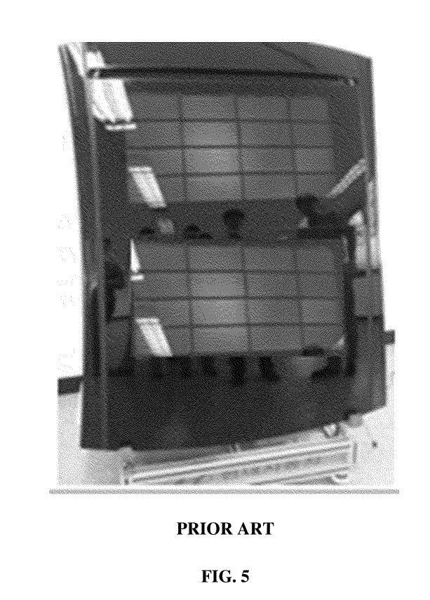

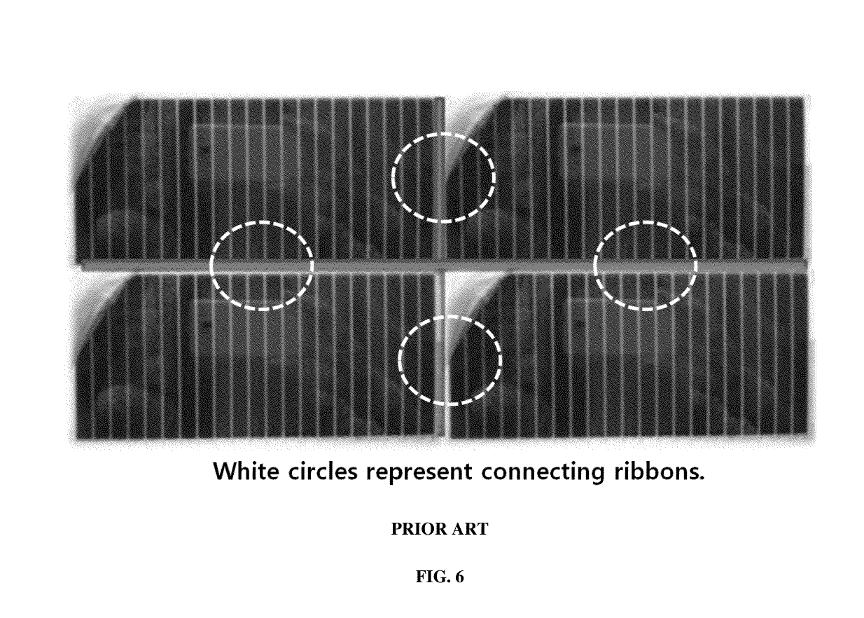

FIG. 3 shows photographic views of an array of a dye-sensitized solar cell which is capable of ensuring transmittance and removing the space between the modules unlike the crystalline solar cells. However, the boundary between the modules may also be exposed as shown in FIGS. 4 and 5. Because the ends between the modules are bonded as illustrated in FIG. 3 fabricate an array by connecting modules of each solar cell as shown in FIG. 6, a space for a connecting ribbon may be required.

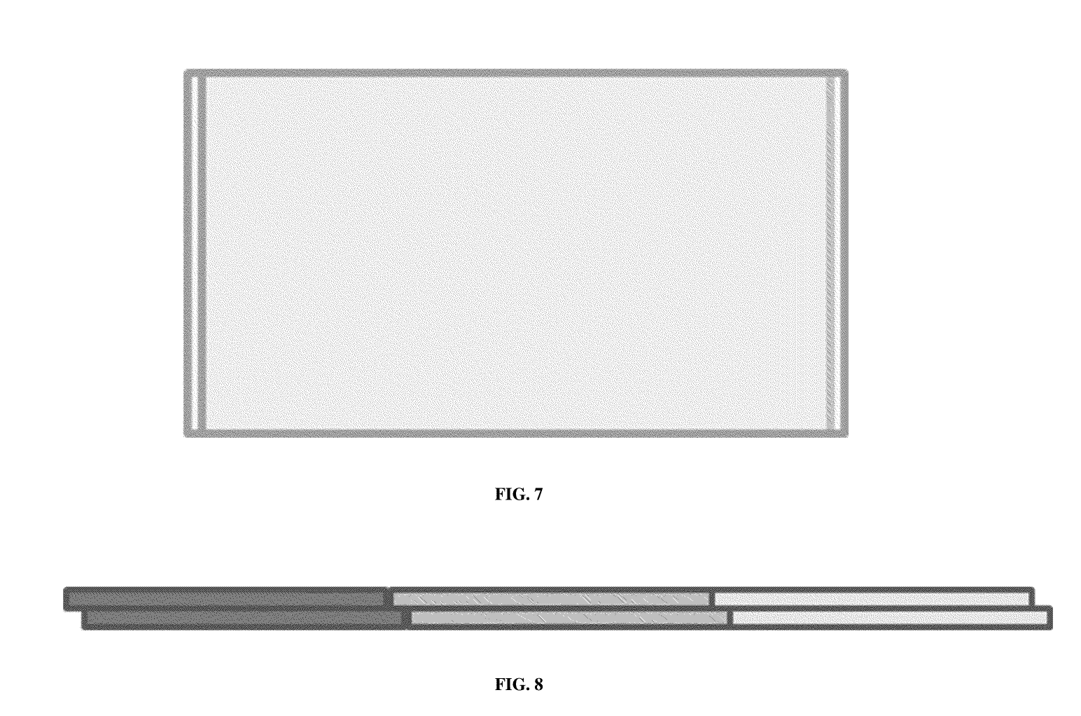

FIG. 7 shows an exemplary module structure which maximizes bonding strength when the upper modules and the lower modules are dislocated and connected thereby minimizing the space for connecting the modules. Accordingly, each glass substrate used in fabrication of the solar cell array may function as a support at the connection parts between the modules. Furthermore, the space for connecting the modules may be minimized by connecting dislocated modules.

Since the bonding strength increases substantially as the contact resistance substantially decreases when the modules are connected as shown in FIG. 7, significant increase in overall efficiency of a solar cell module array may also be obtained.

FIG. 8 schematically shows an exemplary the solar cell modules having a structure capable of minimizing the space between the modules as shown in FIG. 7 are arrayed.

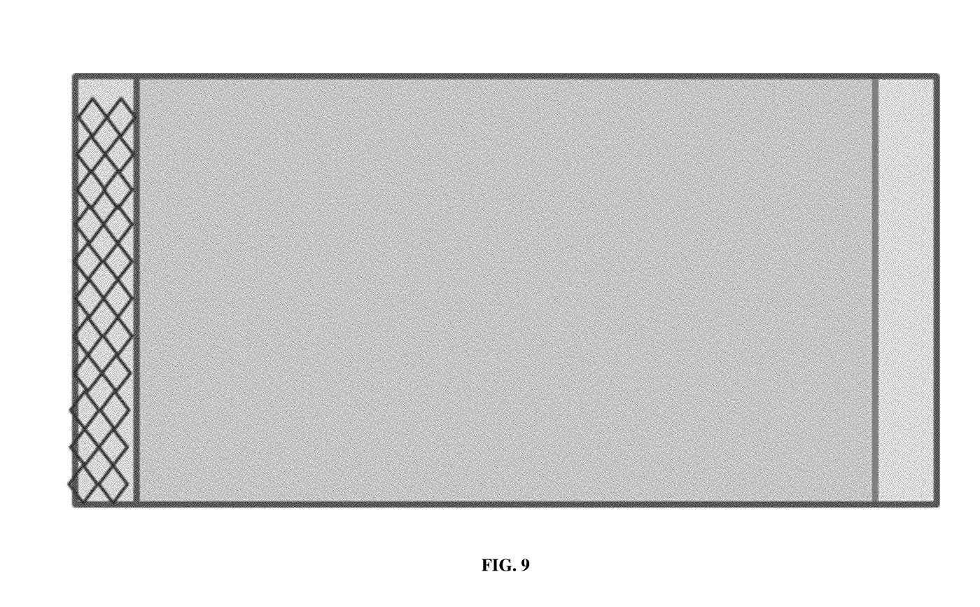

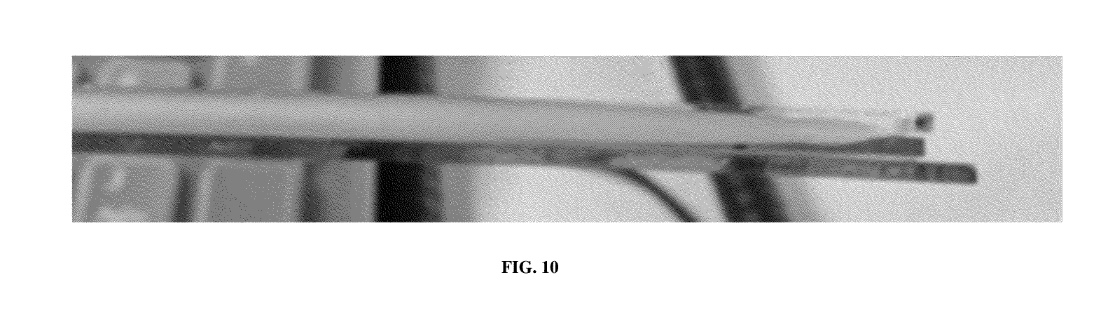

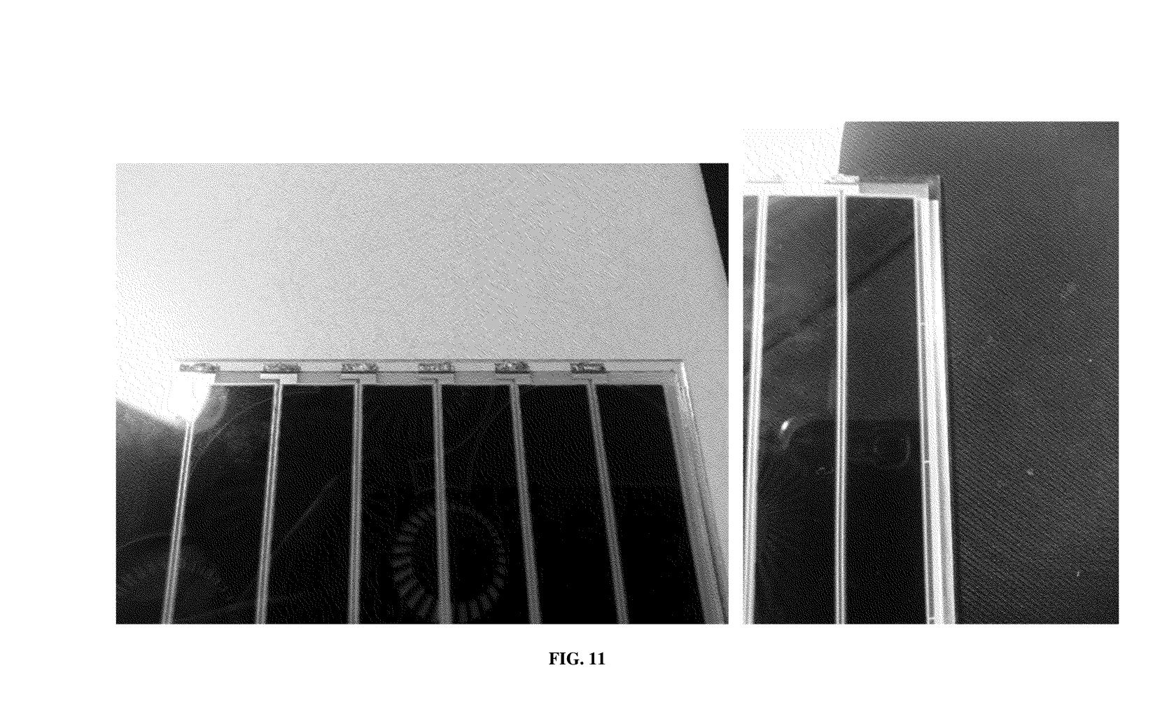

For the connection between the solar cell modules, a conventional ribbon made of silver or copper may be used, and wires may be printed for the connection simultaneously with an electrode which may be printed during the fabrication of a module. Also, in order to maximize light transmittance of the connection wiring, the wires may be formed in a mesh form as shown in FIG. 9, and the resistance between the connections may be minimized by using a transparent conductive film that has been formed on the glass substrate. The module structure for maximizing the efficiency of connecting solar cell modules is shown in FIG. 10.

In various exemplary embodiments, the array method of the present invention may be applied to the installation of a solar cell panel on a panoramic roof of a vehicle. Therefore, the connection gap between the solar cell modules may be minimized and the connection wiring between them may be transparent, thereby maximizing openness or improved light transmittance or sight of the panoramic roof on which the solar cell panel is installed, and further improving appearance of the vehicles.

An exemplary embodiment of the present invention is illustrated in FIG. 11.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A method of fabricating a solar cell array, comprising:
providing a solar cell module which comprises a transparent electrode on a glass or polymer substrate; and
bonding a plurality of the solar cell modules by connecting connection parts of an upper solar cell module and a lower solar cell module, the upper solar cell module and the lower solar cell module are dislocated by about 100 μm to 10 mm to each other.

2. The method of claim 1, further comprising, after providing the solar cell module, forming a pattern having a width of about 1 to 50 μm on a first side of the substrate using one selected from the group consisting of silver (Ag), Ag alloy, copper (Cu), Cu alloy, tin (Sn), Sn alloy, Ag—Cu core shell, Cu—Sn core shell, titanium (Ti), vanadium (V), chromium (Cr), manganese (Mn), cobalt (Co), nickel (Ni), copper (Cu), silver (Ag), gold (Au), iron (Fe) and combinations thereof or the same metal used for the transparent electrode formed on a first side of the substrate.

3. The method according to claim 1, wherein the transparent electrode is a transparent conductive material selected from zinc oxide (ZnO), ZnO:B, ZnO:Al, ZnO:H, tin oxide (SnO₂), SnO₂:F, indium tin oxide (ITO) or fluorine-doped tin oxide (FTO).

4. The method according to claim 2, wherein the pattern is formed on the transparent electrode.

5. The method according to claim 2, wherein the pattern is bonded to the transparent electrode.

6. The method according to claim 2, wherein the pattern has four sides having the same length, and one or more patterns are formed in a shape in which two diagonal lines bisect each other perpendicularly.

7. The method according to claim 1, wherein the connection parts are transparent by using a transparent electrode as a connecting wire.

8. The method according to claim 1, wherein the connection parts are transparent by using the pattern.

9. The method according to claim 2, wherein the pattern having a width of about 1 to about 50 μm has a shape of diamond or honeycomb.

10. The method according to claim 2, wherein the pattern is printed on the substrate by using at least one or more from inkjet printing, screen printing, roll to roll printing and dispenser.

11. A method for manufacturing a panoramic roof for vehicles, comprising the method for fabricating a solar cell array according to claim 1.

12. A solar cell array fabricated by a method of claim 1.

13. A vehicle comprising a solar cell array of claim 12.
